(19) United States
(12) Patent Application Publication
(10) Pub. No.: US 2026/0240039 A1
(43) Pub. Date: Aug. 13, 2026

(54) ELECTRONIC DEVICE

(71) Applicant: Advanced Semiconductor Engineering, Inc., Kaohsiung (TW)

(72) Inventors: Kuofeng HUANG, Kaohsiung (TW); Chih Lung HUNG, Kaohsiung (TW); Hsin-Hua HUANG, Kaohsiung (TW); Chi Hao CHIANG, Kaohsiung (TW); Hsin-Chin CHANG, Kaohsiung (TW)

(73) Assignee: Advanced Semiconductor Engineering, Inc., Kaohsiung (TW)

(21) Appl. No.: 19/050,104

(22) Filed: Feb. 10, 2025

(51) Int. Cl. H01L 25/16; H01L 23/367; H05K 1/14; H05K 1/18

(52) U.S. Cl. CPC H10W 90/00; H05K 1/144; H05K 1/181; H10W 40/22; H05K 2201/042; H05K 2201/10272; H05K 2201/10325; H05K 2201/10378

(57) ABSTRACT

The present disclosure provides an electronic device. The electronic device includes a first stage power module, a second stage power, a first circuit structure, and a connector. The second stage power module is at least partially vertically overlapping the first stage power module. The first circuit structure separates the first stage power module from the second stage power module. The connector is supported by the first circuit structure and configured to transmit an external power to the first stage power module.

### BACKGROUND

### 1. Technical Field

The present disclosure relates to an electronic device.

### 2. Description of the Related Art

Power management integrated circuits (PMICs) leverage System-in-Package (SiP) technology, including double side molding, 2.5D/3D IC, etc., to integrate multiple chips or components into a package. However, to provide different types of power control and to adapt to demands of high-speed data communication, bulky passive components may be needed. As a result, the package size may be increased, and thus the layout design flexibility may be diminished.

### SUMMARY

In some arrangements, an electronic device includes a first stage power module, a second stage power, a first circuit structure, and a connector. The second stage power module is at least partially vertically overlapping the first stage power module. The first circuit structure separates the first stage power module from the second stage power module. The connector is supported by the first circuit structure and configured to transmit an external power to the first stage power module.

In some arrangements, an electronic device includes a first stage power module and a second stage power module. The second stage power module includes a first voltage regulator laterally overlapping the first stage power module and a second voltage regulator vertically overlapping the first stage power module. The first stage power module is configured to provide the first voltage regulator with a first regulated power and to provide the second voltage regulator with a second regulated power substantially the same as the first regulated power.

In some arrangements, an electronic device includes a first stage power module, a second stage power module, and a heat dissipating structure. The second stage power module laterally overlaps the first stage power module and is configured to receive a regulated power from the first stage power module. A vertical dimension of the second stage power module is greater than a vertical dimension of the first stage power module. The heat dissipating structure has a substantially uniform vertical dimension and is configured to be thermally coupled the first power stage module and the second stage power module.

### BRI EF DESCRIPTION OF THE DRAWINGS

Aspects of some arrangements of the present disclosure are best understood from the following detailed description when read with the accompanying figures. It is noted that various structures may not be drawn to scale, and dimensions of the various structures may be arbitrarily increased or reduced for clarity of discussion.

FIG. 1 illustrates a cross-sectional view of an electronic device, in accordance with some arrangements of the present disclosure.

FIG. 2 illustrates a cross-sectional view of a first stage power module, in accordance with some arrangements of the present disclosure.

FIG. 3 illustrates a cross-sectional view of an electronic device, in accordance with some arrangements of the present disclosure.

FIG. 4 illustrates a cross-sectional view of an electronic device, in accordance with some arrangements of the present disclosure.

FIG. 5 illustrates a top view of an electronic device, in accordance with some arrangements of the present disclosure.

FIG. 6 illustrates a cross-sectional view along line A-A′ of FIG. 5, in accordance with some arrangements of the present disclosure.

### DETAILED DESCRIPTION

The following disclosure provides for many different arrangements, or examples, for implementing different features of the provided subject matter. Specific examples of components and arrangements are described as follows to explain certain aspects of the present disclosure. These are, of course, merely examples and are not intended to be limiting. For example, the formation of a first feature over or on a second feature in the description that follows may include arrangements in which the first and second features are formed or disposed in direct contact, and may also include arrangements in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various arrangements and/or configurations discussed.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of arrangements of this disclosure are not deviated from by such arrangement.

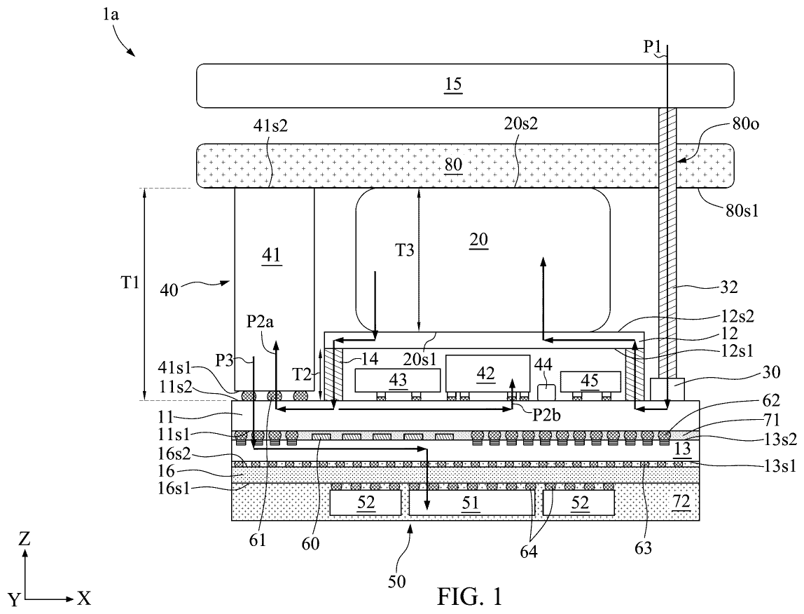

FIG. 1 illustrates a cross-sectional view of an electronic device 1a, in accordance with some arrangements of the present disclosure.

In some arrangements, the electronic device 1a may include circuit structures 11, 12, and 13 (or carriers). Each of the circuit structures 11, 12, and 13 may be formed as a printed circuit board (PCB), flexible printed circuit board (FPCB), or other suitable circuit structures. Each of the circuit structures 11, 12, and 13 may include multiple metal layers separated from one another by layers of dielectric material and interconnected by electrically conductive vias. In some embodiments, each of the circuit structures 11, 12, and 13 may be formed of an epoxy resin, a fiberglass-reinforced epoxy resin, an epoxy resin with inorganic fillers, a ceramic material, or a polymer material such as polyimide. The circuit structure 11 may have a surface 11s1 (or lower surface) and a surface 11s2 (or upper surface) opposite to the surface 11s1. The circuit structure 12 may have a surface 12s1 (or lower surface) and a surface 12s2 (or upper surface) opposite to the surface 12s1. The surface 11s2 of the circuit structure 11 may face the surface 12s1 of the circuit structure 12. The circuit structure 13 may have a surface 13s1 (or lower surface) and a surface 13s2 (or upper surface) opposite to the surface 13s1. Each of the circuit structures 11, 12, and 13 may include a solder resist (not shown) on the upper surface and/or lower surface to fully expose or to expose at least a portion of the conductive pads for electrical connections. The circuit structures 11, 12, and 13 are located at different levels along the substantial Z direction. The circuit structure 12 may be disposed over the circuit structure 11. The circuit structure 11 may be disposed over the circuit structure 13. The circuit structure 12 may have a dimension (e.g., surface area) less than that of the circuit structure 11 (or circuit structure 13). The circuit structure 12 may have a lateral dimension (e.g., width along the substantial X direction) less than that of the circuit structure 11 (or circuit structure 13).

In some arrangements, the electronic device 1a may include an interposer 14, a first stage power module 20, a connector 30, a second stage power module 40, an operating module 50, passive components 60, and a heat dissipating structure 80.

In some arrangements, the interposer 14 may be configured to electrically connect the circuit structures 11 and 12. In some arrangements, the interposer 14 may be disposed between the circuit structures 11 and 12. In some arrangements, the interposer 14 may be disposed on or over the surface 11s2 of the circuit structure 11. In some arrangements, the interposer 14 may include an insulated portion and conductive portions within the insulated portion. In some arrangements, the interposer 14 may include a ring interposer which defines a space for accommodating a portion of the second stage power module 40. In some arrangements, the interposer 14 may function as a height adjusting structure (or height adjusting element) configured to adjust or control the level or height of an upper surface (e.g., surface 20s2) of the first stage power module 20.

In some arrangements, the first stage power module 20 (or first power conversion stage or converter or electrical converter) may be disposed on or over the surface 12s2 of the circuit structure 12. In some arrangements, the first stage power module 20 may be configured to convert a higher voltage (e.g., 48 V) to a lower voltage (e.g., 12 V). In some arrangements, the first stage power module 20 may include at least one power module (or converter), which includes a transistor(s), a diode(s), a capacitor(s), an inductor(s), and/or other suitable elements.

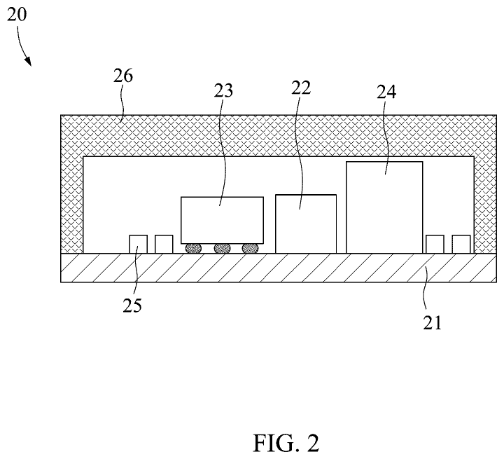

FIG. 2 illustrates a cross-sectional view of the first stage power module 20, in accordance with some arrangements of the present disclosure. In some arrangements, the first stage power module 20 may include a circuit structure 21, an active component 22, a controller 23, passive component 24 and 25, and a housing 26. It should be noted that the first stage power module 20 can include more elements and/or components based on the requirements.

The circuit structure 21 may be formed as a PCB, FPCB, or other suitable circuit structures. The circuit structure 21 may include multiple metal layers separated from one another by layers of dielectric material and interconnected by electrically conductive vias. In some embodiments, the circuit structure 21 may be formed of an epoxy resin, a fiberglass-reinforced epoxy resin, an epoxy resin with inorganic fillers, a ceramic material, or a polymer material such as polyimide. In some arrangements, the first stage power module 20 may include electrical connectors (e.g., solder materials) electrically connecting the circuit structures 12 and 21.

The active component 22, controller 23, passive components 24 and 25 may be disposed on and electrically connected to the circuit structure 21. In some arrangements, the active component 22 may be a transistor, which includes a gate terminal, a drain terminal, and a source terminal. In some arrangements, the controller 23 may be a switch, which is configured to turn on or turn off the active component 22. In some arrangements, the passive component 24 may be configured to regulate the power of the first stage power module 20. The passive component 24 may include an inductor or other suitable elements. In some arrangements, the passive component 25 may be configured to regulate the power of the first stage power module 20. The passive component 25 may include a capacitor (e.g., a deep trench capacitor (DTC), a multi-layer ceramic capacitor (MLCC) or other capacitors), or other suitable elements.

The housing 26 may be disposed on or over the circuit structure 21. The housing 26 may cover the active component 22, controller 23, passive components 24 and 25. In some arrangements, the housing 26 may be configured to transmit the heat from the first stage power module 20 to the surroundings. In some arrangements, the housing 26 may include aluminum (Al), copper (Cu), chromium (Cr), tin (Sn), gold (Au), silver (Ag), nickel (Ni) or stainless steel, or a mixture, an alloy, or other combination thereof.

Please refer back to FIG. 1, the first stage power module 20 may have a surface 20s1 (or a lower surface) and a surface 20s2 (or upper surface) opposite to the surface 20s1. In some arrangements, the surface 20s1 may function as an active surface. In this disclosure, the active surface may refer to a surface on which an active circuit or an active circuit region is disposed or refer to a surface through which a signal (e.g., power signal or data signal) passes.

In some arrangements, the electronic device 1a may include a power delivery board 15 (or external device). The power delivery board 15 may be disposed on or over the first stage power module 20. In some arrangements, the power delivery board 15 may be configured to provide the first stage power module 20 with a relatively great power (e.g., 48 V). In some arrangements, the power delivery board 15 may include a PCB, FPCB, or other suitable circuit structures. One or more electronic components (not shown) may be disposed on or over the power delivery board 15. For example, the electronic device 1a may include a power management integrated circuit (PMIC) die on or within the power delivery board 15.

In some arrangements, the connector 30 may be disposed on or over the surface 11s2 of the circuit structure 11. In some arrangements, the connector 30 may be configured to transmit an external power from the power delivery board 15 to the first stage power module 20. In some arrangements, the connector 30 may include a recess(s) (or slot(s)) functioning as a socket configured to be connected to a conductive element (e.g., conductive element 32) functioning as a plug. In some arrangements, the connector 30 may abut the first stage power module 20.

In some arrangements, the electronic device 1a may include a conductive element 32. The conductive element 32 may be configured to electrically connect the power delivery board 15 and the first stage power module 20. In some arrangements, the conductive element 32 may be electrically connected to the connector 30. In some arrangements, the conductive element 32 may be disposed on or over the connector 30. The conductive element 32 may be detachable from the connector 30. The conductive element 32 may be detachable from the power delivery board 15. In some arrangements, the conductive element 32 may include a pogo pin, conductive pillar, or other suitable conductive elements.

In some arrangements, the surface 20s1 of the first stage power module 20 may be configured to receive a power P1 (or voltage or external power) from the power delivery board 15. In some arrangements, the conductive element 32 may be configured to provide the electrical path conducting the power P1. In some arrangements, the connector 30 may be configured to provide the electrical path conducting the power P1. In some arrangements, the circuit structure 11 may be configured to provide the electrical path conducting the power P1. In some arrangements, the interposer 14 may be configured to provide the electrical path conducting the power P1. In some arrangements, the circuit structure 12 may be configured to provide the electrical path conducting the power P1.

In some arrangements, the second stage power module 40 (or second power conversion stage or converter or electrical converter) may be disposed on or over the surface 11s2 of the circuit structure 11. In some arrangements, the second stage power module 40 may be configured to convert a higher voltage (e.g., 12 V) to a lower voltage (e.g., 8 V, 6 V, 4 V, 2 V, or less). In some arrangements, a portion of the second stage power module 40 may vertically overlap the first stage power module 20 or overlap the first stage power module 20 along the substantial Z direction. In some arrangements, a portion of the second stage power module 40 may laterally overlap the first stage power module 20 or overlap the first stage power module 20 along the substantial X direction. In some arrangements, the second stage power module 40 may include a voltage regulator 41, a voltage regulator 42, a controller 43, a passive component 44, and a voltage regulator 45.

In some arrangements, the voltage regulator 41 (or converter) may be configured to convert a higher voltage (e.g., 12 V) to a lower voltage (e.g., 8 V or 6 V). The voltage regulator 41 may be electrically connected to the circuit structure 11. The voltage regulator 41 may include multiple elements on a circuit structure (e.g., PCB). For example, the voltage regulator 41 may include a transistor(s), a controller(s), and a passive element(s). In some arrangements, the voltage regulator 41 may be configured to transmit a signal(s) with a relatively current (e.g., a current greater than 100 A).

In some arrangements, the voltage regulator 41 may be disposed on or over the surface 11s2 of the circuit structure 11. In some arrangements, the voltage regulator 41 may be free from vertically overlapping the circuit structure 12 or free from overlapping the circuit structure 12 along the substantial Z direction. In some arrangements, the voltage regulator 41 may laterally overlap the circuit structure 12 or overlap the circuit structure 12 along the substantial X direction. In some arrangements, the voltage regulator 41 may laterally overlap the first stage power module 20 or overlap the first stage power module 20 along the substantial X direction. The voltage regulator 41 may have a surface 41s1 (or lower surface) and a surface 41s2 (or upper surface) opposite to the surface 41s1. In some arrangements, the surface 41s1 of the voltage regulator 41 may function as an active surface. In some arrangements, the surface 41s2 of the voltage regulator 41 may be at a level (or elevation) substantially the same as that of the surface 20s2 of the first stage power module 20 with respect to the surface 11s2 of the circuit structure 11.

The voltage regulator 41 may be electrically connected to the circuit structure 11 through electrical connectors 61. In some arrangements, the electrical connectors 61 may include a reflowable material. The electrical connectors 61 may be or include electrical contacts, such as solder balls (e.g., controlled collapse chip connection (C4) bump, a ball grid array (BGA), a land grid array (LGA)), conductive bumps, or the like. The electrical connectors 61 may include alloys of gold and tin solder or alloys of silver and tin solder, or other suitable materials. In other arrangements, the voltage regulator 41 may be electrically connected to the circuit structure 11 by hybrid-bond techniques, which involves a bonding between metallic materials (e.g., a bonding between copper and copper) and a bonding between dielectric materials (e.g., a bonding between oxide and oxide).

In some arrangements, the voltage regulator 41 may be configured to receive a power P2a (or regulated power) from the first stage power module 20. In some arrangements, the circuit structure 12 may be configured to provide the electrical path conducting the power P2a. In some arrangements, the interposer 14 may be configured to provide the electrical path conducting the power P2a. In some arrangements, the circuit structure 11 may be configured to provide the electrical path conducting the power P2a.

In some arrangements, the voltage regulator 42 may be configured to convert a higher voltage (e.g., 12 V) to a lower voltage (e.g., 4 V, 3.3 V, 2 V or less). In some arrangements, the voltage regulator 42 may be disposed within the space defined by the interposer 14. In some arrangements, the voltage regulator 42 may be disposed on or over the surface 11s2 of the circuit structure 11. In some arrangements, the voltage regulator 42 may be disposed between the circuit structures 11 and 12. In some arrangements, the voltage regulator 42 may vertically overlap the first stage power module 20. In some arrangements, the voltage regulator 42 may be configured to receive a power P2b (or regulated power) from the first stage power module 20. In some arrangements, the circuit structure 12 may be configured to provide the electrical path conducting the power P2b. In some arrangements, the interposer 14 may be configured to provide the electrical path conducting the power P2b. In some arrangements, the circuit structure 11 may be configured to provide the electrical path conducting the power P2b.

In some arrangements, the controller 43 may be disposed on or over the surface 11s2 of the circuit structure 11. In some arrangements, the controller 43 may be disposed within the space defined by the interposer 14. In some arrangements, the controller 43 may be electrically connected to the voltage regulator 42 by the circuit structure 11. In some arrangements, the controller 43 may be configured to turn on or turn off the voltage regulator 42.

In some arrangements, the passive component 44 may be disposed on or over the surface 11s2 of the circuit structure 11. In some arrangements, the passive component 44 may include an inductor, capacitor, resistor, or other suitable passive elements. In some arrangements, the passive component 44 may be disposed between the circuit structures 11 and 12.

In some arrangements, the voltage regulator 45 may be disposed on or over the surface 11s2 of the circuit structure 11. In some arrangements, the voltage regulator 45 may be configured to convert a higher voltage (e.g., 12 V) to a lower voltage (e.g., 4 V, 3.3 V, 2 V or less). The voltage regulator 45 may be configured to provide the input/output die of the operating module 50 with a regulated power signal.

In some arrangements, the first stage power module 20 may have a lateral dimension greater than that of the voltage regulator 41. In some arrangements, the first stage power module 20 may have a surface area (e.g., the area of the surface 20s2) greater than that of the voltage regulator 41. In some arrangements, the first stage power module 20 may have a surface area (e.g., the area of the surface 20s2) greater than that of the voltage regulator 42. In some arrangements, the second stage power module 40, including voltage regulators, controllers, passive components and other elements, may have a lateral dimension greater than that of the first stage power module 20. For example, the second stage power module 40, including voltage regulators, controllers, passive components and other elements, may have a surface area greater than that of the first stage power module 20.

In some arrangements, the passive components 60 may be disposed on or over the surface 13s2 of the circuit structure 13. The passive components 60 may be electrically connected to the circuit structure 12. In some arrangements, the passive components 60 may be disposed between the circuit structures 12 and 13. The passive components 60 may be electrically connected to the circuit structure 13. In some arrangements, the passive components 60 may be configured to regulate the power from the second stage power module 40 toward the operating module 50. In some arrangements, the passive components 60 may include capacitors. In some arrangements, the passive components 60 may include an input capacitor (Cin) through which the power flows before being delivered to the second stage power module 40 (e.g., the voltage regulator 41). In some arrangements, the passive components 60 may include an output capacitor through which the power flows after being transmitted from the second stage power module 40 (e.g., the voltage regulator 41).

The electronic device 1a may include electrical connectors 62. The electrical connectors 62 may be disposed between the circuit structures 12 and 13. The electrical connectors 62 may be electrically connect the circuit structures 12 and 13. In some arrangements, the electrical connectors 62 may include a reflowable material. The electrical connectors 62 may be or include electrical contacts, such as solder balls (e.g., controlled collapse chip connection (C4) bump, a ball grid array (BGA), a land grid array (LGA)), conductive bumps, or the like. The electrical connectors 62 may include alloys of gold and tin solder or alloys of silver and tin solder, or other suitable materials. In some arrangements, the dimension (e.g., vertical dimension or thickness) of the passive components 60 may be less than that of the electrical connectors 62.

In some arrangements, the electronic device 1a may include a carrier 16. In some arrangements, the carrier 16 may be disposed on or under the surface 13s1 of the circuit structure 13. In some arrangements, the carrier 16 may include a semiconductor substrate, such as silicon, germanium, and other group III-V and group IV materials. The carrier 16 may include metal lines and vias, including but not limited to through-silicon vias (TSVs) for interconnection. In some arrangements, the carrier 16 may include a wafer, a panel form or other suitable forms. The carrier 16 may have a surface 16s1 (or a lower surface) and a surface 16s2 (or an upper surface) opposite to the surface 16s1.

The carrier 16 may be electrically connected to the circuit structure 13 through electrical connectors 63. The carrier 16 may be configured to support the operating module 50. In some arrangements, the electrical connectors 63 may include a reflowable material. The electrical connectors 63 may be or include electrical contacts, such as solder balls (e.g., controlled collapse chip connection (C4) bump, a ball grid array (BGA), a land grid array (LGA)), conductive bumps, or the like. The electrical connectors 63 may include alloys of gold and tin solder or alloys of silver and tin solder, or other suitable materials.

In some arrangements, the operating module 50 may be disposed on or under the surface 16s1 of the carrier 16. In some arrangements, the operating module 50 may be configured to generate non-power signals, such as analog signals, digital signals, clock signals or other electrical signals other than power signals. The operating module 50 may include electronic components 51 and 52. In some arrangements, the electronic components 51 and 52 may be disposed on or under the surface 16s1 of the carrier 16. In some arrangements, the electronic component 51 may include a processor or other suitable components. In some arrangements, the electronic component 51 may include an active device, such as a central processing unit (CPU), a microprocessor unit (MPU), a graphics processing unit (GPU), a microcontroller unit (MCU), radio frequency integrated circuit (RFIC), an application-specific IC (ASIC), a field-programmable gate array (FPGA), or another type of IC. In some arrangements, the electronic component 52 may include a data storage unit or other suitable components. The electronic component 52 may be electrically connected to the electronic component 51 through the carrier 16. In some arrangements, the electronic component 52 may be configured to storage the signals from the electronic component 51 and/or other devices. In some arrangements, the electronic component 52 may include a high band memory (HBM) die, dynamic random access memory (DRAM) die, static random access memory (SRAM) die, or other suitable memory devices. In some arrangements, the operating module 50 may further include other components, such as input/output dies configured to receive regulated power from the second stage power module 40 and/or transmit a processed signal to other devices (not shown). The electronic components 51 and 52 may be electrically connected to the carrier 16 by electrical connectors 64. In some arrangements, the electrical connectors 64 may include a reflowable material. The electrical connectors 64 may be or include electrical contacts, such as solder balls (e.g., controlled collapse chip connection (C4) bump, a ball grid array (BGA), a land grid array (LGA)), conductive bumps, or the like. The electrical connectors 64 may include alloys of gold and tin solder or alloys of silver and tin solder, or other suitable materials. In other arrangements, the electronic components 51 and 52 may be electrically connected to the carrier 16 by hybrid-bond techniques, which involves a bonding between metallic materials (e.g., a bonding between copper and copper) and a bonding between dielectric materials (e.g., a bonding between oxide and oxide).

In some arrangements, the electronic device 1a may include an encapsulant 71. In some arrangements, the encapsulant 71 may be disposed between the circuit structures 11 and 13. The encapsulant 71 may encapsulate the passive components 60. The encapsulant 71 may include a novolac-based resin, an epoxy-based resin, a silicone-based resin, or another suitable material. The encapsulant 71 may be applied using any of a number of molding techniques, such as compression molding, injection molding, or transfer molding.

In some arrangements, the electronic device 1a may include an encapsulant 72. In some arrangements, the encapsulant 72 may be disposed under the surface 13s1 of the circuit structure 13. The encapsulant 72 may encapsulate the electronic components 51 and 52. In some arrangements, the encapsulant 72 may encapsulate the carrier 16. The encapsulant 72 may include a novolac-based resin, an epoxy-based resin, a silicone-based resin, or another suitable material. The encapsulant 72 may be applied using any of a number of molding techniques, such as compression molding, injection molding, or transfer molding.

The operating module 50 may be configured to receive a power P3 (or regulated power) from the second stage power module 40 (e.g., voltage regulator 41). In some arrangements, the circuit structure 11 may be configured to provide the electrical path (or power path or electrical transmission path) conducting the power P3. In some arrangements, the circuit structure 13 may be configured to provide the electrical path (or power path) conducting the power P3. In some arrangements, the carrier 16 may be configured to provide the electrical path (or power path) conducting the power P3. In some arrangements, the second stage power module 40 may provide the operating module 50 with powers at different levels (e.g., 8 V, 6 V, 4 V, 2 V, or less).

In some arrangements, the heat dissipating structure 80 may be disposed on or over the surface 20s2 of the first stage power module 20. In some arrangements, the heat dissipating structure 80 may be disposed on or over the surface 41s2 of the voltage regulator 41. In some arrangements, the heat dissipating structure 80 may be in direct contact with the surface 20s2 of the first stage power module 20 or indirect contact with the first stage power module 20 by a thermal transmission material (e.g., thermal interface material (TIM)). In some arrangements, the heat dissipating structure 80 may be in direct contact with the surface 41s2 of the voltage regulator 41 or indirect contact with the voltage regulator 41 by a thermal transmission material (e.g., thermal interface material (TIM)). The heat dissipating structure 80 may be configured to transmit heat from the first stage power module 20 and/or the second stage power module 40 to the surrounding environment. In some arrangements, the heat dissipating structure 80 may define an opening 80o for accommodating the conductive element 32. The heat dissipating structure 80 may include a cold plate, which may include a vapor chamber, heat pipe, and/or other suitable elements.

In this arrangement, the second stage power module 40 may include multiple modules with different vertical dimensions (e.g., thickness). For example, the voltage regulator 41 and voltage regulator 42 may have different thicknesses. Some of the modules may have a vertical dimensions (e.g., thickness) greater than that of the first stage power module 20, and some of the modules may have a vertical dimensions (e.g., thickness) less than that of the first stage power module 20. Some of the modules of the second stage power module 40 may have a vertical dimensions (e.g., thickness) less than that of the interposer 14. For example, the voltage regulator 41 may have a thickness T1, the interposer 14 may have a thickness T2 less than the thickness T1, and the first stage power module 20 may have a thickness T3 less than the thickness T1. In some arrangements, the thickness T1 may be greater than or equal to 7 mm, such as 7 mm, 8 mm, 9 mm, 10 mm, or more. In some arrangements, the thickness T2 may be less than 4 mm, such as 4 mm, 3 mm, 2 mm, 1 mm, or less. The In some arrangements, the thickness T3 may range between about 4 mm and 7 mm, such as 4 mm, 5 mm, 6 mm, or 7 mm. In this arrangement, the module(s) of the second stage power module 40 with a thickness greater than that of the first stage power module 20 is disposed at the side of the first stage power module 20, and the module(s) of the second stage power module 40 with a thickness less than that of the first stage power module 20 (or interposer 14) is disposed under the first stage power module 20, thereby reducing the dimension (e.g., surface area extending along the XY plane) of the electronic device 1a.

In this arrangement, the first stage power module 20 and voltage regulator 41 may be designed to deliver a relatively high power output compared to other voltage regulators, such as the voltage regulators 42 and 45, which may result in significant heat generation. To address this, the interposer 14 may function as a height adjusting structure to allow the heat dissipating structure 80 to have a substantially flat (or uniform) surface 80s1 (or a lower surface) in contact with the voltage regulator 41 and the first stage power module 20. Therefore, the voltage regulator 41 may function as a thermal transmission channel for heat dissipation. As a result, the thermal issue of the electronic device 1a may be improved compared to a traditional device.

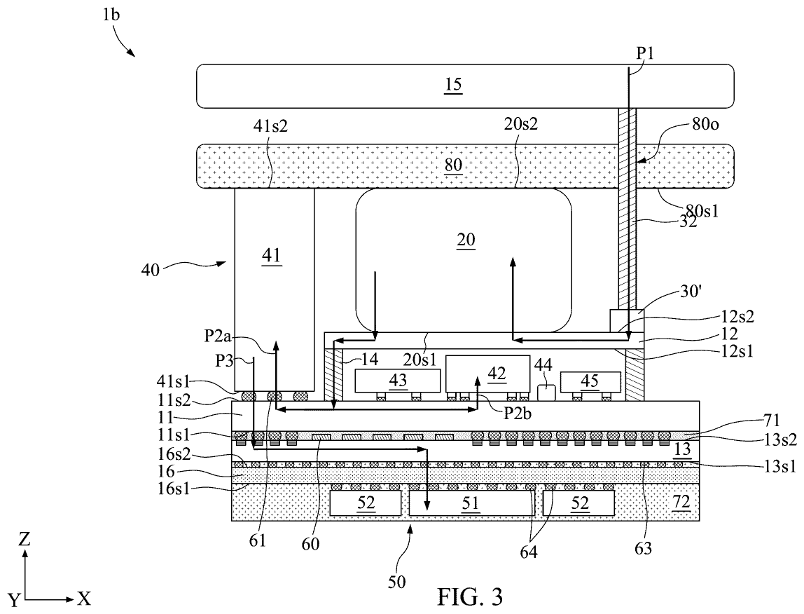

FIG. 3 is a cross-section of an electronic device 1b in accordance with some arrangements of the present disclosure. The electronic device 1b is similar to the electronic device 1a in FIG. 1, differing as follows.

In some arrangements, the electronic device 1b may include a connector 30′. In some arrangements, the connector 30′ may be disposed on or over the surface 12s2 of the circuit structure 12. In some arrangements, the connector 30′ may laterally overlap the first stage power module 20 or overlap the first stage power module 20 along the substantial X direction. In some arrangements, the connector 30′ may be located at a level higher than that of the interposer 14 with respect to the surface 11s2 of the circuit structure 11. In some arrangements, the conductive element 32 may be configured to transmit the power P1. In some arrangements, the connector 30′ may be configured to transmit the power P1. In some arrangements, the circuit structure 12 may be configured to transmit the power P1. In this arrangement, the connector 30′ is much closer to the first stage power module 20, thereby reducing the power loss of the power P1.

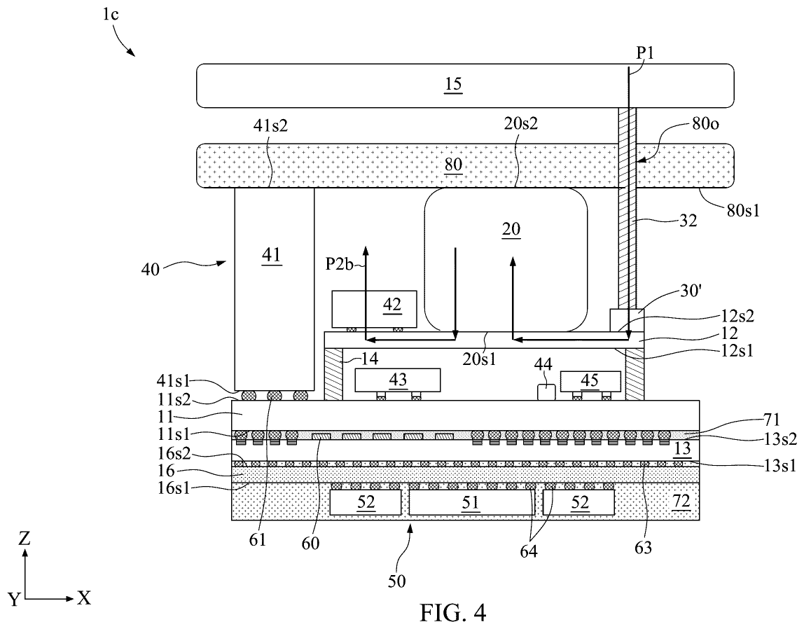

FIG. 4 is a cross-section of an electronic device 1c in accordance with some arrangements of the present disclosure. The electronic device 1c is similar to the electronic device 1b in FIG. 2, differing as follows.

In some arrangements, some of the modules of the second stage power module 40 may be disposed on or over the surface 12s2 of the circuit structure 12. For example, the voltage regulator 42 may be disposed on or over the surface 12s2 of the circuit structure 12. In some arrangements, the voltage regulator 42 may laterally overlap the first stage power module 20 or overlap the first stage power module 20 along the substantial X direction. The circuit structure 12 may be configured to provide an electrical path conducting the power P2b.

In this arrangement, the surface area of the surface 12s2 may be utilized more efficiently, thereby reducing the dimension (e.g., surface area extending along the XY plane) of the electronic device 1c.

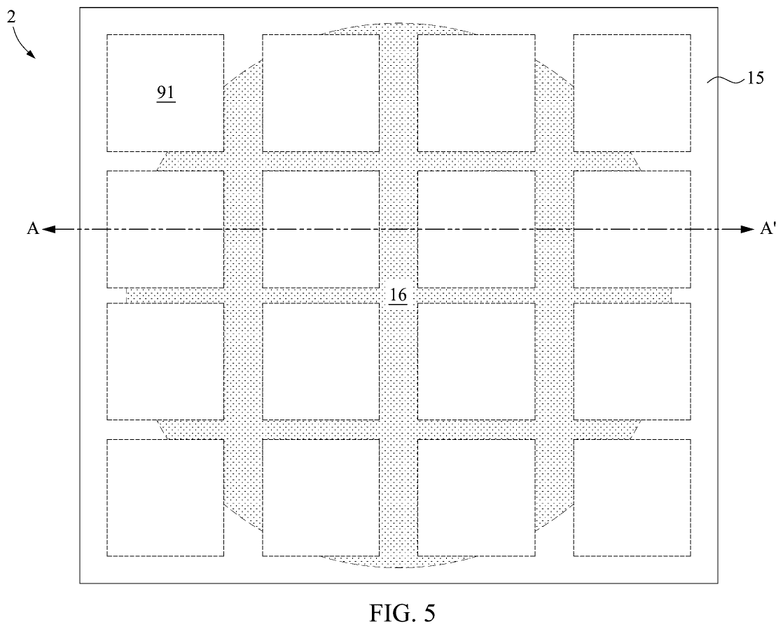

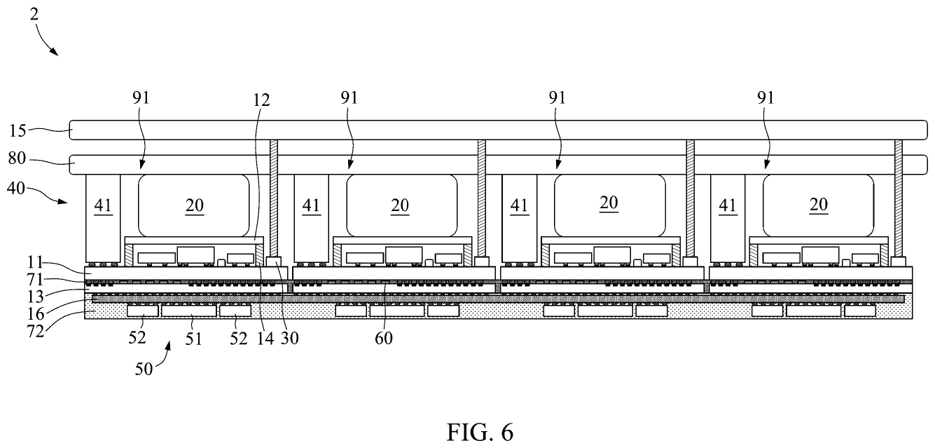

FIGS. 5 and 6 illustrate an electronic device 2, in accordance with some arrangements of the present disclosure. In some arrangements, the electronic device 2 may include multiple packages 91 over the carrier 16. The packages 91 may include a structure the same as or similar to that of one of the electronic devices 1a to 1c. More specifically, the packages 91 may include the structure including the circuit structure 13 and the elements disposed over the circuit structure 13. For example, each of the packages 91 may include the first stage power module 20, the second stage power module 40, and other interconnections for electrical connections. In some arrangements, each of the packages 91 may function as a voltage regulated module configured to provide the operating module 50 with regulated powers. As shown in FIG. 5, the carrier 16 may have a circular profile. The carrier 16 may have a dimension greater than that of the circuit structure 11. The circuit structure 11 may overhang the carrier 16. For example, a portion of the circuit structure 11 may be free from vertically overlapping the carrier 16. The circuit structure 12 may overhang the carrier 16. For example, a portion of the circuit structure 12 may be free from vertically overlapping the carrier 16. The circuit structure 13 may overhang the carrier 16. For example, a portion of the circuit structure 13 may be free from vertically overlapping the carrier 16.

In some arrangements, each of the packages 91 may be configured to supply regulated powers to the operating module 50 independently. By this arrangement, the dimension (e.g., surface area extending along the XY plane) of the electronic device 2 may be reduced.

As used herein, the singular terms “a,” “an,” and “the” may include a plurality of referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation relative to 0° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific arrangements thereof, these descriptions and illustrations do not limit the present disclosure. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other arrangements of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic device, comprising:
a first stage power module;
a second stage power module at least partially vertically overlapping the first stage power module;
a first circuit structure separating the first stage power module from the second stage power module; and
a connector supported by the first circuit structure and configured to transmit an external power to the first stage power module.

2. The electronic device of claim 1, wherein the first stage power module is configured to provide the second stage power module with a first regulated power.

3. The electronic device of claim 1, wherein the first stage power module is electrically connected to the second stage power module by the first circuit structure.

4. The electronic device of claim 3, further comprising:
a height adjusting structure supporting the first circuit structure, wherein the first stage power module is electrically connected to the second stage power module by the height adjusting structure.

5. The electronic device of claim 1, wherein the second stage power module comprises a voltage regulator at a side of the first stage power module and configured to provide a thermal transmission channel.

6. The electronic device of claim 5, wherein an upper surface of the voltage regulator is at a level substantially the same as a level of an upper surface of the first stage power module.

7. The electronic device of claim 5, wherein the voltage regulator laterally overlaps the first stage power module.

8. The electronic device of claim 5, further comprising:
a second circuit structure supporting the voltage regulator and electrically connecting the first stage power module and the voltage regulator.

9. The electronic device of claim 8, further comprising:
an operating module separated from the voltage regulator by the second circuit structure, wherein the voltage regulator is configured to provide the operating module with a second regulated power.

10. The electronic device of claim 5, further comprising:
a heat dissipating structure over the first stage power module and the voltage regulator, wherein the heat dissipating structure is configured to transmit a heat from the first stage power module and a heat from the voltage regulator.

11. An electronic device, comprising:
a first stage power module; and
a second stage power module comprising a first voltage regulator laterally overlapping the first stage power module and a second voltage regulator vertically overlapping the first stage power module,
wherein the first stage power module is configured to provide the first voltage regulator with a first regulated power and to provide the second voltage regulator with a second regulated power substantially the same as the first regulated power.

12. The electronic device of claim 11, further comprising:
an interposer; and
a first circuit structure disposed over the interposer and separating the first stage power module from the second voltage regulator.

13. The electronic device of claim 12, wherein the interposer defines a space for accommodating the second voltage regulator.

14. The electronic device of claim 12, further comprising:
a second circuit structure supporting the interposer,
wherein the first circuit structure and the second circuit structure are collectively configured to provide an electrical path conducting the first regulator power.

15. The electronic device of claim 12, wherein the interposer is configured to transmit an external power to the first stage power module along a first direction and to transmit the first regulated power along a second direction opposite to the first direction.

16. The electronic device of claim 12, wherein the interposer is configured to adjust a height of the first stage power module, and an upper surface of the first stage power module is at a level substantially the same as an upper surface of the first voltage regulator.

17. An electronic device, comprising:
a first stage power module;
a second stage power module laterally overlapping the first stage power module and configured to receive a regulated power from the first stage power module, wherein a vertical dimension of the second stage power module is greater than a vertical dimension of the first stage power module; and
a heat dissipating structure having a substantially uniform vertical dimension and configured to be thermally coupled to the first power stage module and the second stage power module.

18. The electronic device of claim 17, further comprising:
a conductive element configured to provide the first power stage module with an external power, wherein the heat dissipating structure defines an opening for accommodating the conductive element.

19. The electronic device of claim 18, further comprising:
a height adjusting element supporting the first stage power module and configured to provide a first electrical path conducting the regulated power.

20. The electronic device of claim 19, further comprising:
a first circuit structure disposed over the height adjusting element and configured to provide a second electrical path conducting the external power free from laterally overlapping the first electrical path.
